(19) United States
(12) Patent Application Publication
(10) Pub. No.: US 2026/0086163 A1
(43) Pub. Date: Mar. 26, 2026

(54) ELECTROCHEMICAL IMPEDANCE SPECTROSCOPY MEASUREMENT APPARATUS AND METHOD, AND BATTERY SYSTEM

(71) Applicant: SK On Co., Ltd., Seoul (KR)

(72) Inventors: Kyu Min HWANG, Daejeon (KR); Sol San SON, Daejeon (KR); Jae Hee LEE, Daejeon (KR); Hyun Jun LEE, Daejeon (KR); Ung JON, Daejeon (KR)

(21) Appl. No.: 19/325,504

(22) Filed: Sep. 11, 2025

(30) Foreign Application Priority Data
Sep. 20, 2024 (KR) 10-2024-0127347

(51) Int. Cl. G01R 31/389; G01R 31/396; H01M 10/48; H02J 7/00

(52) U.S. Cl. CPC G01R 31/389; G01R 31/396; H01M 10/482; H02J 7/855

(57) ABSTRACT

Proposed are an electrochemical impedance spectroscopy measurement apparatus and method, and a battery system. The electrochemical impedance spectroscopy measurement apparatus includes an EIS measurement part connected to each of a plurality of battery cells included in a battery module, and configured to perform electrochemical impedance spectroscopy (EIS) measurement on each of the plurality of battery cells during AC discharge of the battery module, and an AC discharge switching part connected to the battery module to form an AC discharge path, and configured to supply a driving voltage to a power consumption distribution switching element included in the AC discharge path through a plurality of driving voltage supply paths connected to nodes of the plurality of battery cells electrically connected. Electrochemical impedance spectroscopy (EIS) measurement for the battery may be performed, and impedance measurement may be continuously performed even when a particular node voltage line connected to the battery is disconnected.

### CROSS REFERENCE TO RELATED APPLICATION

The present application claims priority to Korean Patent Application No. 10-2024-0127347, filed Sep. 20, 2024, the entire contents of which is incorporated herein for all purposes by this reference.

### TECHNICAL FIELD

The present disclosure relates to an electrochemical impedance spectroscopy measurement apparatus and method for a battery, and to a battery system.

### BACKGROUND

An electric vehicle refers to a vehicle that operates using electricity, and is equipped with a battery that supplies the electricity. The battery is used as a power source for driving an electric motor used for propulsion of the vehicle.

The electric vehicle is connected to a charger for charging the battery, and the battery is charged by the power supplied from the charger to the electric vehicle.

In such electric vehicles, a battery management system (BMS) is also mounted and used to diagnose and control charging and discharging states of the battery in order to increase the efficiency of the battery and maximize its service life.

In the meantime, in recent years, impedance measurement with electrochemical impedance spectroscopy (EIS) has been used to diagnose the state of the battery, and a great deal of research have been conducted on methods capable of diagnosing battery defects using electrochemical impedance spectroscopy.

The foregoing is intended merely to aid in the understanding of the background of the present disclosure, and is not intended to mean that the present disclosure falls within the purview of the related art that is already known to those skilled in the art.

### SUMMARY

According to an aspect of the present disclosure, the present disclosure is directed to providing an electrochemical impedance spectroscopy measurement apparatus and method, and a battery system that are capable of performing electrochemical impedance spectroscopy (EIS) measurement for a battery.

According to an aspect of the present disclosure, the present disclosure is directed to providing an electrochemical impedance spectroscopy measurement apparatus and method, and a battery system that are capable of outputting a driving voltage through a bypass path depending on the condition in order to operate a switching element that distributes power consumption when a particular voltage line connected to a battery is disconnected during electrochemical impedance spectroscopy (EIS) measurement for the battery.

An electrochemical impedance spectroscopy measurement apparatus and method, and a battery system according to an aspect of the present disclosure may be widely applicable to electric vehicles, battery charging stations, and other green technology fields such as solar power generation and wind power generation using batteries.

An electrochemical impedance spectroscopy measurement apparatus and method, and a battery system according to an aspect of the present disclosure are applicable to eco-friendly electric vehicles or hybrid vehicles to curb air pollution and greenhouse gas emission and to prevent climate change.

According to an aspect of the present disclosure, there is provided an electrochemical impedance spectroscopy measurement apparatus including: an EIS measurement part connected to each of a plurality of battery cells included in a battery module, and configured to perform electrochemical impedance spectroscopy (EIS) measurement on each of the plurality of battery cells during AC discharge of the battery module; and an AC discharge switching part connected to the battery module to form an AC discharge path, and configured to supply a driving voltage to a power consumption distribution switching element included in the AC discharge path through a plurality of driving voltage supply paths connected to nodes of the plurality of battery cells electrically connected.

According to an embodiment, the AC discharge switching part may include: an AC generation switching part electrically connected to the battery module including the plurality of battery cells, and including a first switching element for generating AC; one or more power consumption distribution parts connected in series to the AC generation switching part, and each including a second switching element for receiving the driving voltage through the plurality of driving voltage supply paths connected to the nodes of the plurality of battery cells; a switching control part configured to control an on/off operation of the AC generation switching part according to a determined frequency for electrochemical impedance spectroscopy (EIS) measurement; and a driving voltage output part configured to form the plurality of driving voltage supply paths through a plurality of driving voltage output elements connected to the nodes of the plurality of battery cells, wherein output terminals of the plurality of driving voltage output elements are connected to a single line in common and connected to the power consumption distribution part, and when any one of the plurality of driving voltage output elements is disconnected, the driving voltage output element connected to the node of the battery cell with the highest node voltage among the remaining driving voltage output elements outputs the driving voltage.

According to an embodiment, the first switching element may be a field effect transistor.

According to an embodiment, the power consumption distribution part may include: a second switching element connected in series to the battery module including the plurality of battery cells; a resistance element positioned between a gate terminal of the second switching element and output terminals of the plurality of driving voltage output elements, and connected thereto; and a semiconductor device of which an input terminal is connected to a source terminal of the second switching element and of which an output terminal is connected to the gate terminal of the second switching element, and configured to induce a constant voltage output.

According to an embodiment, the second switching element may be a field effect transistor, and the semiconductor device may be a zener diode.

According to an embodiment, the second switching element may be continuously maintained in a turned-on state by causing the voltage at the gate terminal of the second switching element to be output higher than the voltage at the source terminal and to be output equal to or higher than a breakdown voltage of the semiconductor device.

According to an embodiment, the plurality of driving voltage output elements may be a plurality of diodes of which input terminals are respectively connected to the nodes of the plurality of battery cells and of which the output terminals are connected to the single line in common, and may be connected to the power consumption distribution part, and configured to output the highest node voltage among node voltages connected to the nodes of the plurality of battery cells to the power consumption distribution part.

According to an embodiment, the AC discharge switching part may further include: a sensing resistor part of which one end is connected to a negative terminal of the battery module including the plurality of battery cells and of which the other end is connected to the AC generation switching part, wherein the switching control part may be configured to control an on/off cycle of the AC generation switching part by measuring a voltage applied to the sensing resistor part so as to maintain a determined AC frequency for electrochemical impedance spectroscopy (EIS) measurement.

According to an embodiment, the sensing resistor part may include one or more resistance elements.

According to an aspect of the present disclosure, there is provided an electrochemical impedance spectroscopy measurement method including: generating, by an AC discharge switching part electrically connected to a battery module including a plurality of battery cells, AC corresponding to a frequency for electrochemical impedance spectroscopy (EIS) measurement for the battery module; performing, by an EIS measurement part connected to nodes of the plurality of battery cells included in the battery module, electrochemical impedance spectroscopy (EIS) measurement on each of the plurality of battery cells; and responding to, by the AC discharge switching part when any one of a plurality of driving voltage supply paths connected to the nodes of the plurality of battery cells electrically connected to supply a driving voltage to a switching element included in an AC discharge path is disconnected during electrochemical impedance spectroscopy (EIS) measurement for each of the plurality of battery cells, disconnection of the driving voltage by outputting the highest node voltage among the remaining driving voltage supply paths.

According to an embodiment, in the step of responding to the disconnection of the driving voltage, when a connection line for the highest node voltage is disconnected while the highest node voltage is output among node voltages connected to and output from the nodes of the plurality of battery cells, the AC discharge switching part may output the next-highest node voltage among the remaining node voltages excluding the highest node voltage through the plurality of driving voltage supply paths.

According to an embodiment, in the step of responding to the disconnection of the driving voltage, while the highest node voltage is output among node voltages connected to and output from the nodes of the plurality of battery cells, when any one of connection lines to the remaining nodes other than the node having the highest output is disconnected, the AC discharge switching part may maintain the output of the highest node voltage that is currently output through the plurality of driving voltage supply paths.

According to an embodiment, in the step of performing electrochemical impedance spectroscopy (EIS) measurement, during electrochemical impedance spectroscopy (EIS) measurement for each of the plurality of battery cells, a switching control part of the AC discharge switching part may control an on/off cycle of an AC generation switching part by measuring a voltage applied to a sensing resistor part so as to maintain a determined AC frequency for electrochemical impedance spectroscopy (EIS) measurement.

According to an aspect of the present disclosure, there is provided a battery system including: a battery module including a plurality of battery cells; an EIS measurement device connected to each of a plurality of battery cells included in the battery module, and configured to perform electrochemical impedance spectroscopy (EIS) measurement on each of the plurality of battery cells during AC discharge of the battery module; and an AC discharge switching device connected to the battery module to form an AC discharge path, and configured to supply a driving voltage to a power consumption distribution switching element included in the AC discharge path through a plurality of driving voltage supply paths connected to nodes of the plurality of battery cells.

According to an embodiment, the AC discharge switching device may include: an AC generation switching part electrically connected to the battery module including the plurality of battery cells, and including a first switching element for generating AC; one or more power consumption distribution parts connected in series to the AC generation switching part, and each including a second switching element for receiving the driving voltage through the plurality of driving voltage supply paths connected to the nodes of the plurality of battery cells; a switching control part configured to control an on/off operation of the AC generation switching part according to a determined frequency for electrochemical impedance spectroscopy (EIS) measurement; and a driving voltage output part configured to form the plurality of driving voltage supply paths through a plurality of driving voltage output elements connected to the nodes of the plurality of battery cells, wherein output terminals of the plurality of driving voltage output elements are connected to a single line in common and connected to the power consumption distribution part, and when any one of the plurality of driving voltage output elements is disconnected, the driving voltage output element connected to the node of the battery cell with the highest node voltage among the remaining driving voltage output elements outputs the driving voltage.

According to an embodiment, the AC discharge switching device may further include: a sensing resistor part positioned between, connecting the AC generation switching part and the battery module including the plurality of battery cells, the switching control part is configured to control an on/off cycle of the AC generation switching part by measuring a voltage applied to the sensing resistor part so as to maintain a determined AC frequency for electrochemical impedance spectroscopy (EIS) measurement.

The features and advantages of the present disclosure will be more clearly understood from the following detailed description based on the accompanying drawings.

The terms and words used in the present specification and claims should not be interpreted as being limited to typical meanings and dictionary definitions, but should be interpreted as having meanings and concepts relevant to the technical scope of the present disclosure based on the rule according to which an inventor can appropriately define the concept of the term to describe most appropriately the best method he or she knows for carrying out the present disclosure.

According to an embodiment of the present disclosure, electrochemical impedance spectroscopy (EIS) measurement for the battery can be performed.

According to an embodiment of the present disclosure, during electrochemical impedance spectroscopy (EIS) measurement for the battery, the driving voltage can be output through the bypass path in order to operate the switching element that distribute power consumption even when a particular voltage line connected to the battery is disconnected.

According to an embodiment of the present disclosure, the situation in which electrochemical impedance spectroscopy (EIS) measurement becomes impossible due to external factors such as disconnection can be prevented by multiplying (redundancy) the output of the driving voltage for operating the switching element that distribute power consumption during AC discharge.

According to an embodiment of the present disclosure, power consumption generated due to AC discharge during electrochemical impedance spectroscopy (EIS) measurement can be distributed.

According to an embodiment of the present disclosure, the durability and stability of the entire circuit of the AC discharge switching part for AC discharge can be improved.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a diagram illustrating an electrochemical impedance spectroscopy measurement apparatus according to an embodiment;

FIG. 2 is a diagram illustrating a circuit configuration of an AC discharge switching part in an electrochemical impedance spectroscopy measurement apparatus according to an embodiment;

FIG. 3 is a diagram illustrating an electrochemical impedance spectroscopy measurement apparatus including an AC discharge switching part that further includes a sensing resistor part, according to an embodiment;

FIG. 4 is a diagram illustrating an operation in a case in which the highest node voltage connection line among a plurality of connection lines connected to nodes of a plurality of battery cells is disconnected, in an electrochemical impedance spectroscopy measurement apparatus according to an embodiment;

FIG. 5 is a diagram illustrating an operation in a case in which excluding the highest node voltage connection line connected to the nodes of the plurality of battery cells, any one of the remaining node voltage connection lines is disconnected, in an electrochemical impedance spectroscopy measurement apparatus according to an embodiment;

FIG. 6 is a flowchart illustrating each step of an electrochemical impedance spectroscopy measurement method according to an embodiment;

FIG. 7 is a diagram illustrating a step of responding to disconnection of a driving voltage in an electrochemical impedance spectroscopy measurement method according to an embodiment; and

FIG. 8 is a diagram illustrating a battery system according to an embodiment.

### DETAILED DESCRIPTION

Hereinafter, the present disclosure will be described in detail (with reference to the accompanying drawings). However, this is merely illustrative and the present disclosure is not limited to a specific embodiment described by way of example.

The drawings may be schematic or exaggerated to describe an embodiment.

As used herein, the terms “have”, “may have”, “include”, or “may include” a feature (e.g., a number, function, operation, or an element such as a component) indicate the existence of the feature and do not exclude the existence of other features.

Hereinafter, an embodiment of the present disclosure will be described in detail with reference to the accompanying drawings.

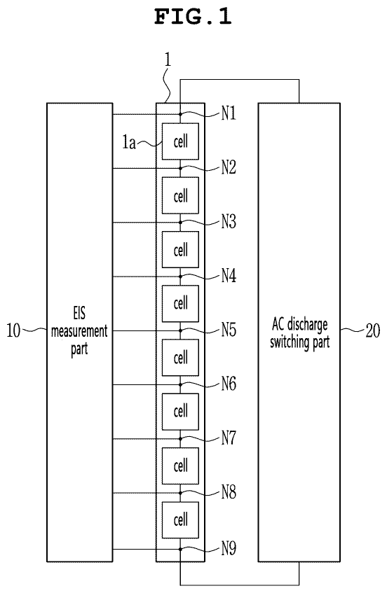

FIG. 1 is a diagram illustrating an electrochemical impedance spectroscopy measurement apparatus according to an embodiment.

Referring to FIG. 1, the electrochemical impedance spectroscopy measurement apparatus according to the present disclosure may include: an EIS measurement part 10 connected to each of a plurality of battery cells 1a included in a battery module 1, and configured to perform electrochemical impedance spectroscopy (EIS) measurement on each of the plurality of battery cells 1a during AC discharge of the battery module 1; and an AC discharge switching part 20 connected to the battery module 1 to form an AC discharge path, and configured to supply a driving voltage to a power consumption distribution switching element included in the AC discharge path through a plurality of driving voltage supply paths connected to nodes of the plurality of battery cells 1a that are electrically connected.

In the battery module 1, the plurality of battery cells 1a may be electrically connected. In the battery module 1, the plurality of battery cells 1a may be connected in series, connected in parallel, or connected in a combination of series and parallel.

The EIS measurement part 10 may be connected to battery module 1 and performs electrochemical impedance spectroscopy (EIS) measurement to diagnose the state of the battery module 1. The EIS measurement part 10 may be connected to the nodes (N1 to N9) of the plurality of battery cells 1a included in the battery module 1 and perform electrochemical impedance spectroscopy (EIS) measurement on each battery cell 1a, and may diagnose the state of the battery module 1. The nodes (N1 to N9) of the plurality of battery cells 1a may be connection lines that make connections between the battery cells 1a.

Electrochemical impedance spectroscopy (EIS) is a technology for diagnosing a battery by measuring the sum of components that appear when alternating current or voltage is applied, that is, the impedance. Electrochemical impedance spectroscopy (EIS) may diagnose manufacturing defects, internal short circuits, overcharging, overdischarging, or remaining capacity of the battery. Electrochemical impedance spectroscopy (EIS) can reduce inspection time and lower costs compared to conventional battery inspection methods.

The AC discharge switching part 20 may perform AC discharge based on the battery module 1 so that the EIS measurement part 10 can perform impedance measurement with electrochemical impedance spectroscopy (EIS) on each of the plurality of battery cells 1a included in the battery module 1. In this case, the discharged AC may be perturbation current.

The AC discharge switching part 20 may be electrically connected to the battery module 1, which includes the plurality of battery cells 1a, to form the AC discharge path. The AC discharge switching part 20 may be connected in series to the battery module 1, which includes the plurality of battery cells 1a. The AC discharge switching part 20 may include a plurality of driving voltage supply paths that are connected to the nodes (N1 to N9) of the plurality of battery cells 1a to form the AC discharge path and receive a driving voltage from the node voltages formed at the respective nodes. The AC discharge switching part 20 may supply the driving voltage to a power consumption distribution switching element included in the AC discharge path through the plurality of driving voltage supply paths. The AC discharge switching part 20 may supply, as the driving voltage, the highest node voltage among the node voltages formed at the nodes (N1 to N9) of the plurality of battery cells 1a through the plurality of driving voltage supply paths.

Through this, the AC discharge switching part 20 may perform AC discharge based on the battery module 1, and the EIS measurement part 10 may perform electrochemical impedance spectroscopy (EIS) measurement on each battery cell 1a.

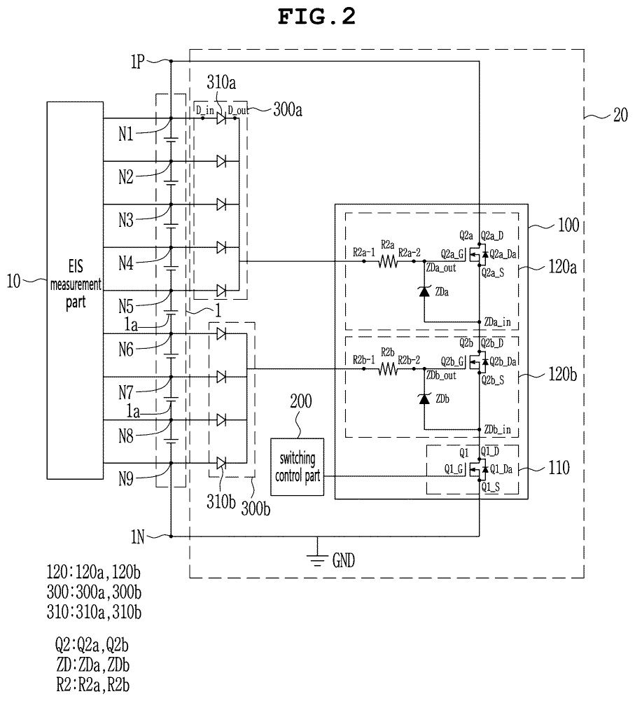

The plurality of driving voltage supply paths are realized as driving voltage output elements connected to the nodes (N1 to N9) of the plurality of battery cells 1a, and will be described in detail below with reference to FIG. 2.

The power consumption distribution switching element, which receives the driving voltage through the plurality of driving voltage supply paths, is an element capable of on/off switching. The power consumption distribution switching element may distribute the power consumption that occurs when the AC discharge switching part 20 discharges AC using the battery module 1. The power consumption distribution switching element may be a second switching element (Q2) of the power consumption distribution part 120 shown in FIG. 2.

FIG. 2 is a diagram illustrating a circuit configuration of an AC discharge switching part in an electrochemical impedance spectroscopy measurement apparatus according to an embodiment.

Referring to FIG. 2, in the electrochemical impedance spectroscopy measurement apparatus according to the present disclosure, the AC discharge switching part 20 may include an AC generation switching part 110, a power consumption distribution part 120, a switching control part 200, and a driving voltage output part 300. The AC generation switching part 110 is connected in series to the battery module 1 including the plurality of battery cells 1a, and includes a first switching element (Q1) for generating AC. One or more power consumption distribution parts 120 are connected in series to the AC generation switching part 110, and each includes a second switching element (Q2) for receiving the driving voltage through the plurality of driving voltage supply paths connected to the nodes (N1 to N9) of the plurality of battery cells 1a. The switching control part 200 is configured to control an on/off operation of the AC generation switching part 110 according to a determined frequency for electrochemical impedance spectroscopy (EIS) measurement. The driving voltage output part 300 is configured to the plurality of driving voltage supply paths through a plurality of driving voltage output elements 310 connected to the nodes (N1 to N9) of the plurality of battery cells 1a. Output terminals of the plurality of driving voltage output elements 310 are connected to a single line in common and connected to the power consumption distribution part 120. When any one of the plurality of driving voltage output elements 310 is disconnected, the driving voltage output element connected to the node of the battery cell with the highest node voltage among the remaining driving voltage output elements outputs the driving voltage.

In FIG. 2, reference numeral 100 denotes a discharge path formation part that forms the AC discharge path, and the discharge path formation part 100 may include the AC generation switching part 110 and the power consumption distribution part 120.

The AC generation switching part 110 may perform a switching operation to generate AC corresponding to the determined frequency for electrochemical impedance spectroscopy (EIS) measurement. The AC generation switching part 110 may include the first switching element (Q1), and the first switching element (Q1) may be a field effect transistor (FET). The source terminal (Q1_S) of the first switching element (Q1) may be connected in series to negative terminal (1N) of the battery module (1), the drain terminal (Q1_D) of the first switching element (Q1) may be connected to the power consumption distribution part 120, and the gate terminal (Q1_G) of the first switching element (Q1) may be connected to the switching control part 200.

The AC generation switching part 110 may further include a diode (Q1_Da) connected to the first switching element (Q1). The anode of the diode (Q1_Da) may be connected to the source terminal (Q1_S) of the first switching element (Q1), and the cathode of the diode (Q1_Da) may be connected to the drain terminal (Q1_D) of the first switching element (Q1).

The switching control part 200 may control the AC generation switching part 110, and the AC generation switching part 110 may be switched under the control of the switching control part 200. The AC generation switching part 110 may remain turned off so that no AC flows when the EIS measurement part 10 does not perform electrochemical impedance spectroscopy (EIS) measurement. The AC generation switching part 110 may be repeatedly switched on and off for AC generation when the EIS measurement part 10 performs electrochemical impedance spectroscopy (EIS) measurement. The switching control part 200 may be realized together with the EIS measurement part 10 in a single EIS chip.

One or more power consumption distribution parts 120 may be connected in series to the AC generation switching part 110. The power consumption distribution part 120 may distribute the power consumption generated when AC is discharged from the battery module 1 through the AC generation switching part 110. Herein, the power consumption (P) may be expressed as “module voltage (V)×perturbation current (I)”.

The power consumption distribution part 120 may include: the second switching element (Q2) connected in series to the battery module 1 including the plurality of battery cells 1a; a resistance element (R2) positioned between the gate terminal of the second switching element (Q2) and the output terminals (D_out) of the plurality of driving voltage output elements 310 and connected thereto; and a semiconductor device (ZD) having the input terminal connected to the source terminal of the second switching element (Q2) and having the output terminal connected to the gate terminal of the second switching element (Q2), and inducing a constant voltage output. The power consumption distribution part 120 causes the voltage at the gate terminal of the voltage second switching element (Q2) to be output higher than the voltage at the source terminal and to be output equal to or higher than the breakdown voltage of the semiconductor device (ZD), so that the second switching element (Q2) is continuously maintained in a turned-on state.

The second switching element (Q2) may be a field effect transistor, and the semiconductor device (ZD) may be a zener diode.

The resistance element (R2) may be connected to a line to which the output terminals (D_out) of the plurality of driving voltage output elements 310 are connected in common.

Since the voltage applied from the battery module 1 to the first switching element (Q1) is large, a plurality of the power consumption distribution parts 120, rather than one, may be formed for voltage distribution. In the present disclosure, two power consumption distribution parts are provided as shown in FIG. 2. However, the present disclosure is not particularly limited to the number.

Referring to FIG. 2, the power consumption distribution part 120 may include a first power consumption distribution part 120a and a second power consumption distribution part 120b.

The first power consumption distribution part 120a may include: a second-a switching element (Q2a) positioned between the positive terminal (1P) of the battery module 1 including the plurality of battery cells 1a and the AC generation switching part 110 and connected thereto in series; a first resistance element (R2a) positioned between the gate terminal (Q2a_G) of the second-a switching element Q2a and the output terminals (D_out) of the plurality of driving voltage output elements 310a and connected thereto; and a first semiconductor device (ZDa) having the input terminal (ZDa_in) connected to the source terminal (Q2a_S) of the second-a switching element (Q2a) and having the output terminal (ZDa_out) connected to the gate terminal (Q2a_G) of the second-a switching element (Q2a), and including a constant voltage output. The first power consumption distribution part 120a causes the voltage at the gate terminal (Q2a_G) of the second-a switching element (Q2a) to be output higher than the voltage at the source terminal (Q2a_S) and to be output equal to or higher than the breakdown voltage of the first semiconductor device (ZDa), so that the second-a switching element (Q2a) is continuously maintained in a turned-on state.

The source terminal (Q2a_S) of the second-a switching element (Q2a) may be connected in series to the drain terminal (Q2b_D) of a second-b switching element (Q2b), the drain terminal (Q2a_D) of the second-a switching element (Q2a) may be connected in series to the positive terminal (1P) of the battery module 1, and the gate terminal (Q2a_G) of the second-a switching element (Q2a) may be connected to a first driving voltage output part 300a.

The first power consumption distribution part 120a may further include a second-a diode (Q2a_Da) connected to the second-a switching element (Q2a). The anode of the second-a diode (Q2a_Da) may be connected to the source terminal (Q2a_S) of the second-a switching element (Q2a), and the cathode of the second-a diode (Q2a_Da) may be connected to the drain terminal (Q2a_D) of the second-a switching element (Q2a).

One end (R2a-1) of the first resistance element (R2a) may be connected to a common line to which the output terminals (D_out) of the plurality of driving voltage output elements 310a are connected, and the other end (R2a-2) of the first resistance element (R2a) may be connected to the gate terminal (Q2a_G) of the second-a switching element(Q2a). Herein, the plurality of driving voltage output elements 310a may constitute the first driving voltage output part 300a.

The second power consumption distribution part 120b may include: a second-b switching element (Q2b) positioned between the first power consumption distribution part 120a and the AC generation switching part 110 and connected thereto in series; a second resistance element (R2b) positioned between the gate terminal (Q2b_G) of the second-b switching element (Q2b) and the output terminals (D_out) of the plurality of driving voltage output elements 310b and connected thereto; and a second semiconductor device (ZDb) having the input terminal (ZDb_in) connected to the source terminal (Q2b_S) of the second-b switching element (Q2b) and having the output terminal (ZDb_out) connected to the gate terminal (Q2b_G) of the second-b switching element (Q2b), and inducing a constant voltage output. The second power consumption distribution part 120b causes the voltage at the gate terminal (Q2b_G) of the second-b switching element (Q2b) to be output higher than the voltage at the source terminal (Q2b_S) and to be output as high as the breakdown voltage of the second semiconductor device (ZDb), so that the second-b switching element (Q2b) is continuously maintained in a turned-on state.

The source terminal (Q2b_S) of the second-b switching element (Q2b) may be connected in series to the drain terminal (Q1_D) of the first switching element (Q1) of the AC generation switching part 110, the drain terminal (Q2b_D) of the second-b switching element (Q2b) may be connected in series to the source terminal (Q2a_S) of the second-a switching element (Q2a), and the gate terminal (Q2a_G) of the second-b switching element (Q2b) may be connected to a second driving voltage output part 300b.

The second power consumption distribution part 120b may further include a second-b diode (Q2b_Da) connected to the second-b switching element (Q2b). The anode of the second-b diode (Q2b_Da) may be connected to the source terminal (Q2b_S) of the second-b switching element (Q2b), and the cathode of the second-b diode (Q2b_Da) may be connected to the drain terminal (Q2b_D) of the second-b switching element (Q2b).

One end (R2b-1) of the second resistance element (R2b) may be connected to a common line to which the output terminals (D_out) of the plurality of driving voltage output elements 310b are connected, and the other end (R2b-2) of the second resistance element (R2b) may be connected to the gate terminal (Q2b_G) of the second-b switching element (Q2b). Herein, the plurality of driving voltage output elements 310b may constitute the second driving voltage output part 300b.

The electrochemical impedance spectroscopy (EIS) measurement apparatus according to the present disclosure may include two driving voltage output parts corresponding to the case in which two power consumption distribution part are included.

Accordingly, the power consumption distribution part 120 distributes the voltage between the positive terminal (1P) and the negative terminal (1N) of the battery module 1 through the circuit configuration using the second switching element (Q2), which is a field effect transistor, the resistance element (R2), and the semiconductor device (ZD), which is a zener diode, thereby reducing the impact of the withstand voltage stress on the first switching element (Q1) of the AC generation switching part 110 and managing heat generation.

The driving voltage output part 300 may include the plurality of driving voltage output elements 310 to output the driving voltage for driving the second switching element (Q2) of the power consumption distribution part 120 from the battery module 1 including the plurality of battery cells 1a.

The plurality of driving voltage output elements 310 are a plurality of diodes having the input terminals (D_in) connected to the nodes of the plurality of battery cells 1a, respectively, and having the output terminals (D_out) connected to a single line in common and being connected to the power consumption distribution part 120. The plurality of diodes may output the highest node voltage among the node voltages connected to the nodes of the plurality of battery cells 1a to the power consumption distribution part 120. The plurality of diodes may be connected in a forward direction.

By using diodes as the plurality of driving voltage output elements 310 and connecting them in a forward direction, a function of outputting the highest node voltage among the node voltages connected to and output from the battery cells 1a may be performed. The voltage output from the diode connected to the node with the highest note voltage to one common line may be prevented from flowing back to the battery cell 1a through the other diodes connected to the same common line.

The plurality of driving voltage output elements 310 are connected to the plurality of nodes that the plurality of battery cells 1a have, and may supply the highest node voltage among the plurality of node voltages of the plurality of battery cells 1a as the driving voltage to the power consumption distribution part 120. Herein, when a particular connection line that has supplied the highest node voltage among the nodes connected to the plurality of battery cells 1a is disconnected, the plurality of driving voltage output elements 310 may output the next-highest node voltage among the remaining nodes connected to the plurality of battery cells 1a that are not disconnected. That is, the plurality of driving voltage output elements 310 may output the next-highest node voltage among the nodes connected to the plurality of battery cells 1a.

Referring to FIG. 2, the driving voltage output part 300 may include the first driving voltage output part 300a connected to the first power consumption distribution part 120a, and the second driving voltage output part 300b connected to the second power consumption distribution part 120b.

The first driving voltage output part 300a may include the plurality of driving voltage output elements 310a. The input terminals (D_in) of the plurality of driving voltage output elements 310a may be connected to the nodes of the plurality of battery cells 1a, and the output terminals (D_out) of the plurality of driving voltage output elements 310a may be connected to one common line, and the one common line may be connected to the first power consumption distribution part 120a.

The second driving voltage output part 300b may include the plurality of driving voltage output elements 310b. The input terminals (D_in) of the plurality of driving voltage output elements 310b may be connected to the nodes of the plurality of battery cells 1a, and the output terminals (D_out) of the plurality of driving voltage output elements 310b may be connected to one common line, and the one common line may be connected to the second power consumption distribution part 120b.

Accordingly, the driving voltage output part 300 may output the driving voltage to the power consumption distribution part 120 while connected to the plurality of battery cells 1a during electrochemical impedance spectroscopy (EIS) measurement. When the connection line of the node that has supplied the highest node voltage is disconnected among the nodes connected to the plurality of battery cells 1a, the remaining connected driving voltage output elements 310 of the driving voltage output part 300 output the next-highest node voltage among the node voltages connected to the plurality of battery cells 1a and supply the same to the power consumption distribution part 120. Through this, the power consumption distribution part 120 may be continuously turned on.

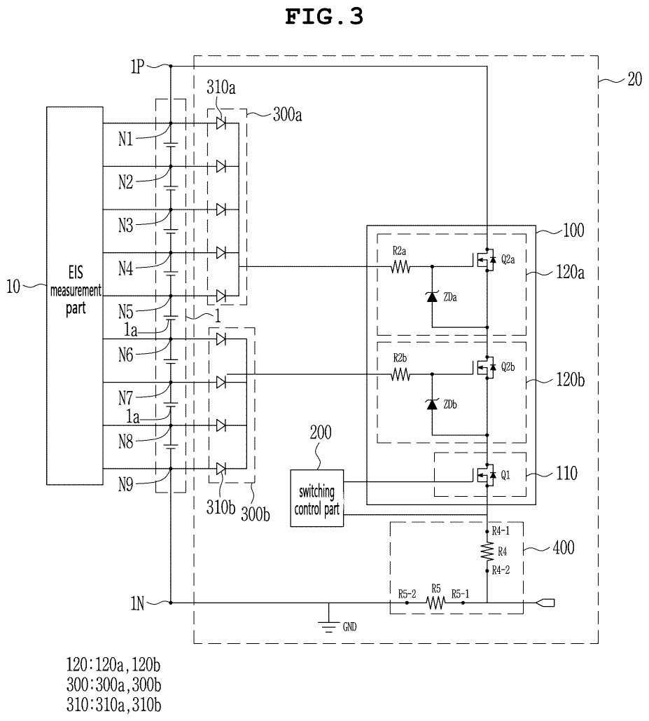

FIG. 3 is a diagram illustrating an electrochemical impedance spectroscopy measurement apparatus including an AC discharge switching part that further includes a sensing resistor part, according to an embodiment.

Referring to FIG. 3, in the electrochemical impedance spectroscopy measurement apparatus according to the present disclosure, the AC discharge switching part 20 may further include a sensing resistor part 400 positioned between, connecting the AC generation switching part 110 and the battery module 1 including the plurality of battery cells 1a. The switching control part 200 may measure the voltage applied to the sensing resistor part 400 and control the on/off cycle of the AC generation switching part 110 so that the determined AC frequency for electrochemical impedance spectroscopy (EIS) measurement is maintained.

The sensing resistor part 400 may include one or more resistance elements to identify AC flowing for electrochemical impedance spectroscopy (EIS) measurement in the form of a voltage. Referring to FIG. 3, the sensing resistor part 400 may connect two resistance elements (R4 and R5) in series. One end (R4-1) of the resistor (R4) of the sensing resistor part 400 may be connected in series to the first switching element (Q1) of the AC generation switching part 110 and the other end (R4-2) of the resistor (R4) may be connected to one end (R5-1) of the other resistor (R5). The other end (R5-2) of the resistor (R5) of the sensing resistor part 400 may be connected to the negative terminal (1N) of the battery module 1 and connected to the ground (GND).

The switching control part 200 may measure the voltage of the opposite ends of the entire sensing resistor part 400 to determine whether AC generated by the switching operation of the AC generation switching part 110 corresponds to the frequency for electrochemical impedance spectroscopy (EIS) measurement. Through this, the switching control part 200 may control the on/off cycle of the AC generation switching part 110 so as to maintain the determined AC frequency for electrochemical impedance spectroscopy (EIS) measurement.

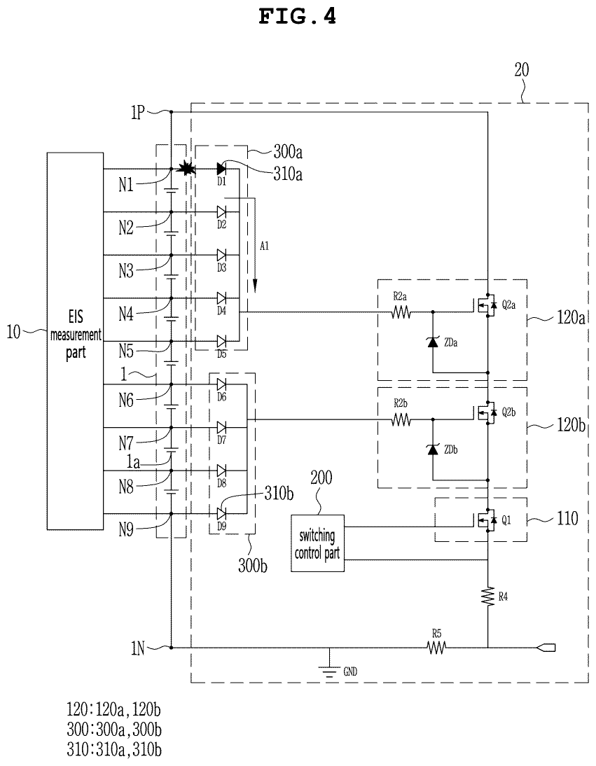

FIG. 4 is a diagram illustrating an operation in a case in which the highest node voltage connection line among a plurality of connection lines connected to nodes of a plurality of battery cells is disconnected, in an electrochemical impedance spectroscopy measurement apparatus according to an embodiment.

Referring to FIG. 4, a response to disconnection in the case in which the highest node voltage connection line connected to the nodes (N1 to N5) of the plurality of battery cells 1a is disconnected will be described on the basis of the first driving voltage output part 300a and the first power consumption distribution part 120a matched to each other.

In order for the EIS measurement part 10 to perform electrochemical impedance spectroscopy (EIS) measurement on each battery cell 1a of the battery module 1, the AC discharge switching part 20 may perform AC discharge.

The switching control part 200 of the AC discharge switching part 20 may generate AC by repeatedly controlling the on/off operation of the first switching element (Q1) of the AC generation switching part 110. Simultaneously, AC discharge from the battery module 1 may be performed.

Herein, the EIS measurement part 10 may perform electrochemical impedance spectroscopy (EIS) measurement on each battery cell 1a.

During electrochemical impedance spectroscopy (EIS) measurement by the EIS measurement part 10, the plurality of first driving voltage output elements 310a connected to the nodes (N1 to N5) of the plurality of battery cells 1a may output the highest node voltage among the nodes (N1 to N5) of the plurality of battery cells 1a and supply the same to the first power consumption distribution part 120a. The plurality of first driving voltage output elements 310a may operate the second-a switching element (Q2a) of the first power consumption distribution part 120a, and may distribute the power consumption generated during AC discharge. Through this, by distributing the voltage between the positive terminal (1P) and the negative terminal (1N) of the battery module 1, the impact of the withstand voltage stress on the first switching element (Q1) of the AC generation switching part 110 may be reduced and heat generation may be managed.

Referring to FIG. 4, regarding the plurality of first driving voltage output elements 310a, diodes D1 to D5 are respectively connected to the nodes (N1 to N5) of the plurality of battery cells 1a through the connection lines. Through diode D1 connected to node (N1) having the highest node voltage among the plurality of battery cells 1a, the driving voltage may be output to the first power consumption distribution part 120a.

Herein, when the connection line to diode D1 connected to the node (N1) having the highest node voltage among the plurality of battery cells 1a is disconnected, any one of the plurality of first driving voltage output elements 310a connected to the nodes of the plurality of battery cells 1a that are not disconnected may output the currently highest node voltage of the node of the battery cell 1a. That is, among diodes D2 to D5 that are the plurality of first driving voltage output elements 310a that are not disconnected, outputting (A1) of the driving voltage may be performed through diode D2 connected to the node (N2) of the battery cell 1a having the currently highest node voltage.

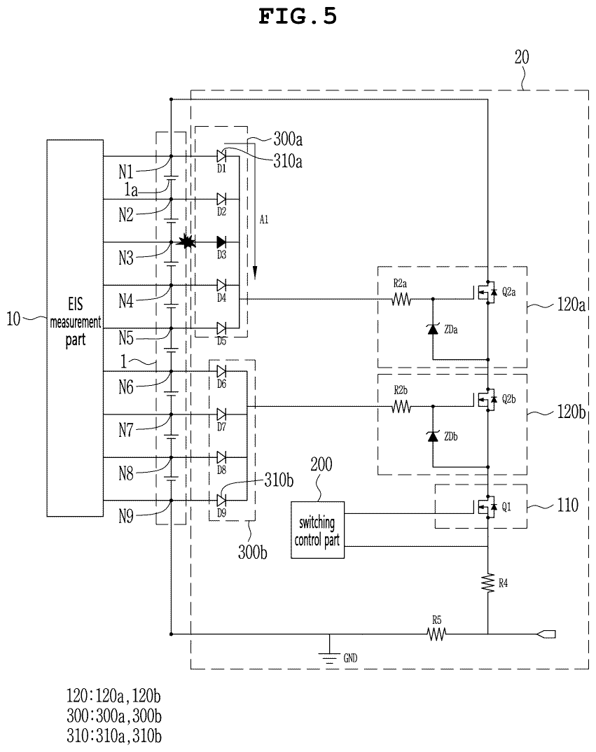

FIG. 5 is a diagram illustrating an operation in a case in which excluding the highest node voltage connection line connected to the nodes of the plurality of battery cells, any one of the remaining node voltage connection lines is disconnected, in an electrochemical impedance spectroscopy measurement apparatus according to an embodiment.

Referring to FIG. 5, a response to disconnection in the case in which a connection line other than the highest node voltage connection line among the plurality of connection lines connected to the nodes of the plurality of battery cells is disconnected will be described on the basis of the first driving voltage output part 300a and the first power consumption distribution part 120a matched to each other.

The AC discharge switching part 20 may generate AC through repeated control of the on/off operation of the first switching element (Q1) of the AC generation switching part 110 to form the AC discharge path from the battery module 1. Through this, the EIS measurement part 10 may perform electrochemical impedance spectroscopy (EIS) measurement on each of the plurality of battery cells 1a.

During electrochemical impedance spectroscopy (EIS) measurement by the EIS measurement part 10, the plurality of first driving voltage output elements 310a connected to the nodes of the plurality of battery cells 1a may output the highest node voltage among the nodes (N1 to N5) of the plurality of battery cells 1a and supply the same to the first power consumption distribution part 120a. The second-a switching element (Q2a) of the first power consumption distribution part 120a may be operated, and power consumption generated during AC discharge may be distributed.

Referring to FIG. 5, regarding the plurality of first driving voltage output elements 310a, diodes D1 to D5 are respectively connected to the nodes (N1 to N5) of the plurality of battery cells 1a through the connection lines. Through diode D1 connected to node (N1) having the highest node voltage among the plurality of battery cells 1a, the driving voltage may be output to the first power consumption distribution part 120a.

Herein, other than the connection line to diode D1 connected to the node (N1) having the highest node voltage among the plurality of battery cells 1a, any one of the connection lines to the nodes (N2 to N5) of the plurality of battery cells 1a connected to the remaining node voltages may be disconnected. For example, among the node voltages of the remaining nodes (N2 to N5) excluding the highest node voltage, when the connection line to diode D3 connected to the node (N3) of the plurality of battery cells 1a is disconnected, outputting (A1) of the driving voltage may be maintained through diode D1 connected to the node (N1) having the highest node voltage among the plurality of battery cells 1a. That is, the plurality of first driving voltage output elements 310a including diodes D1 to D5 may perform the function of outputting only the highest node voltage formed among the connection lines connected to the nodes (N1 to N5) of the plurality of battery cells 1a.

Accordingly, even when a particular connection line among the connection lines connected to the nodes (N1 to N9) of the plurality of battery cells 1a is disconnected, the driving voltage output part 300 according to the present disclosure may respond to this disconnection by forming a bypass path depending on the condition. This can prevent a situation in which electrochemical impedance spectroscopy (EIS) measurement for all the battery cells 1a of the battery module 1 becomes impossible. In addition, by multiplexing the output of the driving voltage for operating the second switching element (Q2) that distributes power consumption, the durability and stability of the entire circuit of the AC discharge switching part 20 may be improved.

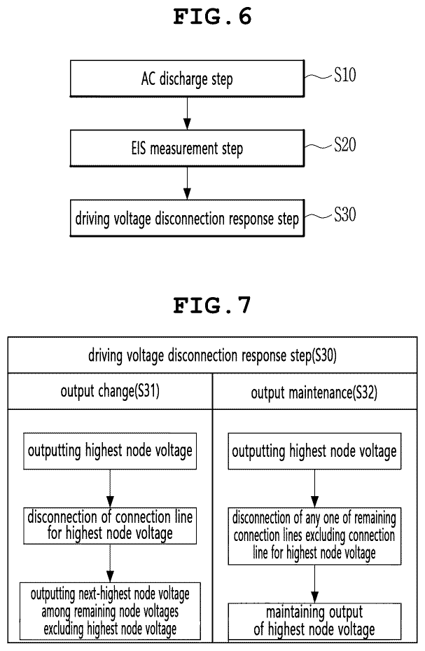

FIG. 6 is a flowchart illustrating each step of an electrochemical impedance spectroscopy measurement method according to an embodiment.

Referring to FIG. 6, the electrochemical impedance spectroscopy measurement method according to the present disclosure may include: generating, by the AC discharge switching part 20 connected to the battery module 1 including the plurality of battery cells 1a, AC corresponding to a frequency for electrochemical impedance spectroscopy (EIS) measurement for the battery module 1 in step S10; performing, by the EIS measurement part 10 connected to the nodes of the plurality of battery cells 1a included in the battery module 1, electrochemical impedance spectroscopy (EIS) measurement on each of the plurality of battery cells 1a included in the battery module 1 in step S20; and responding to, by the AC discharge switching part 20 when any one of the plurality of driving voltage supply paths connected to the nodes of the plurality of battery cells (1a) electrically connected to supply a driving voltage to the power consumption distribution switching element included in the AC discharge path is disconnected during electrochemical impedance spectroscopy (EIS) measurement for each of the plurality of battery cells 1a, disconnection of the driving voltage by outputting the highest node voltage among the remaining driving voltage supply paths.

In the battery module 1, the plurality of battery cells 1a may be electrically connected. In the battery module 1, the plurality of battery cells 1a may be connected in series, connected in parallel, or connected in a combination of series and parallel.

In the step of generating AC in step S10, the AC discharge switching part 20 forms the AC discharge path so that AC discharge from the battery module 1 may be performed, in order for the EIS measurement part 10 to perform electrochemical impedance spectroscopy (EIS) measurement. In this case, the discharged AC may be perturbation current.

In the step of performing electrochemical impedance spectroscopy (EIS) measurement in step S20, the EIS measurement part 10 performs electrochemical impedance spectroscopy (EIS) measurement on each of the plurality of battery cells 1a included in the battery module 1 while the AC discharge switching part 20 causes AC discharge from the battery module 1.

In the step of performing electrochemical impedance spectroscopy (EIS) measurement in step S20, the switching control part 200 may measure the voltage of the opposite ends of the sensing resistor part 400 to determine whether AC generated by the switching operation of the AC generation switching part 110 corresponds to the frequency for electrochemical impedance spectroscopy (EIS) measurement. Through this, the on/off cycle of the AC generation switching part 110 may be controlled so as to maintain the determined AC frequency for electrochemical impedance spectroscopy (EIS) measurement.

In the step of responding to the disconnection of the driving voltage in step S30, using the plurality of multiplexed driving voltage supply paths, the driving voltage is supplied through a bypass path when any one driving voltage supply path is disconnected.

In the step of responding to the disconnection of the driving voltage in step S30, the plurality of driving voltage supply paths may be the plurality of driving voltage output elements. The plurality of driving voltage output elements may be diodes as shown in FIG. 2. Referring to FIG. 2, the plurality of driving voltage output elements 310 may be respectively connected to the nodes (N1 to N9) of the plurality of battery cells 1a and may operate such that the highest node voltage is output from the plurality of battery cells 1a.

Accordingly, in the present disclosure, the AC discharge switching part 20 forms the AC discharge path so that AC discharge from the battery module 1 may be performed, the EIS measurement part 10 may perform electrochemical impedance spectroscopy (EIS) measurement on each battery cell 1a. In addition, through multiplexing by the plurality of driving voltage supply paths, even when any one connection line connected to the plurality of driving voltage output elements 310 among the nodes (N1 to N9) connected to the plurality of battery cells 1a is disconnected, electrochemical impedance spectroscopy (EIS) measurement for each battery cell 1a may be continuously performed.

FIG. 7 is a diagram illustrating a step of coping with disconnection of a driving voltage in an electrochemical impedance spectroscopy measurement method according to an embodiment.

Referring to FIG. 7, in the electrochemical impedance spectroscopy measurement method according to the present disclosure, in the step of responding to the disconnection of the driving voltage in step S30, when the connection line for the highest node voltage is disconnected while the highest node voltage is output among the node voltages connected to and output from the nodes of the plurality of battery cells 1a, the AC discharge switching part 20 may output the next-highest node voltage among the remaining node voltages excluding the highest node voltage through the plurality of driving voltage supply paths. Accordingly, the second switching element (Q2) of the power consumption distribution part 120 may be maintained in the turned-on state, and the AC discharge path may be maintained. In this way, AC discharge from the battery module 1 may be performed, so a state in which electrochemical impedance spectroscopy (EIS) measurement is possible may be maintained.

This may correspond to a driving voltage output change step S31 shown in FIG. 7. Additionally, as the connection line outputting the highest node voltage is disconnected, the driving voltage output part 300 of the AC discharge switching part 20 may switch the output of the node voltages from the plurality of battery cells 1a. In this way, the driving voltage output change step S31 for operating the switching element that distributes power consumption may be understood with reference to FIG. 4.

In addition, in the electrochemical impedance spectroscopy measurement method according to the present disclosure, in the step of responding to the disconnection of the driving voltage in step S30, when any one of the connection lines to the remaining nodes other than the node having the highest output is disconnected while the highest node voltage is output among the node voltages connected to and output from the nodes of the plurality of battery cells 1a, the AC discharge switching part 20 may maintain the output of the highest node voltage that is currently output through the plurality of driving voltage supply paths.

This may correspond to a driving voltage output maintenance step S32 shown in FIG. 7. In addition, while the highest node voltage is output among the node voltages connected to and output from the nodes of the plurality of battery cells 1a, when any one of the connection lines to the nodes other than the node having the highest node voltage is disconnected, the AC discharge switching part 20 may continuously maintain the current output of the highest node voltage through the plurality of driving voltage output elements 310. In this way, the driving voltage output maintenance step S32 for operating the switching element that distributes power consumption may be understood with reference to FIG. 5.

Accordingly, in the present disclosure, when electrochemical impedance spectroscopy (EIS) measurement is performed on the battery cells 1a of the battery module 1, even if a particular voltage line connected to each node of the battery cells 1a is disconnected, this disconnection is dealt with depending on the condition and the output of the driving voltage is maintained or changed. Therefore, regardless of external factors such as disconnection, the present disclosure can prevent the situation in which electrochemical impedance spectroscopy (EIS) measurement for all the battery cells 1a of the battery module 1 becomes impossible.

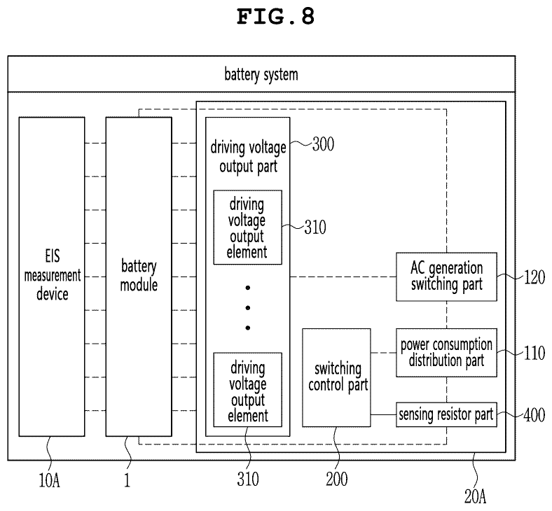

FIG. 8 is a configuration diagram illustrating a battery system according to an embodiment.

Referring to FIG. 8, the battery system according to the present disclosure may include: the battery module 1 including the plurality of battery cells 1a; an EIS measurement device 10A connected to each of the plurality of battery cells 1a included in the battery module 1, and configured to perform electrochemical impedance spectroscopy (EIS) measurement on each of the plurality of battery cells 1a during AC discharge of the battery module 1; and an AC discharge switching device 20A connected to the battery module 1 to form the AC discharge path, and configured to supply the driving voltage to the power consumption distribution switching element included in the AC discharge path through the plurality of driving voltage supply paths connected to the nodes of the plurality of battery cells 1a.

In the battery module 1, the plurality of battery cells 1a may be electrically connected. In the battery module 1, the plurality of battery cells 1a may be connected in series, connected in parallel, or connected in a combination of series and parallel.

The EIS measurement device 10A and the AC discharge switching device 20A have the same configuration and operation as the EIS measurement part 10 and the AC discharge switching part 20 described above with reference to FIGS. 1 to 6. Thus, the technical contents described above may be referenced with FIGS. 1 to 6.

The EIS measurement device 10A may be connected to the nodes (N1 to N9) of the plurality of battery cells 1a included in the battery module 1 and perform electrochemical impedance spectroscopy (EIS) measurement on each battery cell 1a, and may diagnose the state of the battery module 1. The nodes (N1 to N9) of the plurality of battery cells 1a may be connection lines that make connections between the battery cells 1a.

The AC discharge switching device 20A may include a plurality of driving voltage supply paths that are connected to the nodes (N1 to N9) of the plurality of battery cells 1a to form the AC discharge path and receive a driving voltage from the node voltages formed at the respective nodes. The AC discharge switching device 20A may supply the driving voltage to a power consumption distribution switching element included in the AC discharge path through the plurality of driving voltage supply paths. The AC discharge switching device 20A may supply, as the driving voltage, the highest node voltage among the node voltages formed at the nodes (N1 to N9) of the plurality of battery cells 1a through the plurality of driving voltage supply paths.

In the battery system according to the present disclosure, the AC discharge switching device 20A forms the AC discharge path so that AC discharge from the battery module 1 may be performed, the EIS measurement device 10A may perform electrochemical impedance spectroscopy (EIS) measurement, and the state of the battery module may be diagnosed using this measurement.

In addition, referring to FIG. 8, the AC discharge switching device 20A of the battery system according to the present disclosure may include the AC generation switching part 110, the power consumption distribution part 120, the switching control part 200, the driving voltage output part 300, and a sensing resistor part 400. The AC generation switching part 110 is connected in series to the battery module 1 including the plurality of battery cells 1a, and includes the first switching element (Q1) for generating AC. One or more power consumption distribution parts 120 are connected in series to the AC generation switching part 110, and each includes the second switching element (Q2) for receiving the driving voltage through the plurality of driving voltage supply paths connected to the nodes (N1 to N9) of the plurality of battery cells 1a. The switching control part 200 is configured to control the on/off operation of the AC generation switching part 110 according to the determined frequency for electrochemical impedance spectroscopy (EIS) measurement. The driving voltage output part 300 is configured to the plurality of driving voltage supply paths through the plurality of driving voltage output elements 310 connected to the nodes (N1 to N9) of the plurality of battery cells 1a. The output terminals of the plurality of driving voltage output elements 310 are connected to a single line in common and connected to the power consumption distribution part 120. When any one of the plurality of driving voltage output elements 310 is disconnected, the driving voltage output element 310 connected to the node of the battery cell 1a with the highest node voltage among the remaining driving voltage output elements 310 outputs the driving voltage. The sensing resistor part 400 is positioned between, connecting the AC generation switching part 110 and the battery module 1 including the plurality of battery cells 1a. The switching control part 200 may be configured to control the on/off cycle of the AC generation switching part 110 by measuring the voltage applied to the sensing resistor part 400 so as to maintain the determined AC frequency for electrochemical impedance spectroscopy (EIS) measurement.

The AC generation switching part 110 may perform a switching operation to generate AC corresponding to the determined frequency for electrochemical impedance spectroscopy (EIS) measurement.

The power consumption distribution part 120 may distribute the power consumption that occurs when AC is discharged using the battery module 1 including the plurality of battery cells 1a.

The input terminals of the driving voltage output part 300 are connected to the nodes of the plurality of battery cells 1a and the output terminals of the driving voltage output part 300 are connected to one line in common, so the plurality of driving voltage supply paths may be formed through the plurality of driving voltage output elements 310 connected to the power consumption distribution part 120. By forming the plurality of driving voltage supply paths, when any one of the connection lines connected to the nodes of the plurality of battery cells 1a is disconnected, a bypass path may be formed depending on the condition.

One end of the sensing resistor part 400 may be connected to the negative terminal of the battery module 1 and the other end thereof may be connected to the AC generation switching part 110.

Accordingly, in the battery system according to the present disclosure, the AC discharge switching device 20A may form the AC discharge path of the battery module 1 required for electrochemical impedance spectroscopy (EIS) measurement by the EIS measurement device 10A. In particular, even if a particular connection line connected to the nodes of the plurality of battery cells 1a is disconnected, the driving voltage output part 300 immediately deals with this disconnection and outputs the driving voltage, thereby maintaining AC discharge. This can prevent a situation in which electrochemical impedance spectroscopy (EIS) measurement becomes impossible due to the disconnection of a particular connection line among the connection lines connected to the nodes of the plurality of battery cells 1a.

The present disclosure has been described in detail above through detailed embodiments. The above description is only an example to which the principle of the present disclosure is applied, and other constitutions may be further included or may be substituted with different ones without departing from the scope of the present disclosure.

What is claimed is:

1. An electrochemical impedance spectroscopy measurement apparatus, comprising:
an EIS measurement part connected to each of a plurality of battery cells included in a battery module, and configured to perform electrochemical impedance spectroscopy (EIS) measurement on each of the plurality of battery cells during AC discharge of the battery module; and
an AC discharge switching part connected to the battery module to form an AC discharge path, and configured to supply a driving voltage to a power consumption distribution switching element included in the AC discharge path through a plurality of driving voltage supply paths connected to nodes of the plurality of battery cells electrically connected.

2. The electrochemical impedance spectroscopy measurement apparatus of claim 1, wherein the AC discharge switching part comprises:
an AC generation switching part electrically connected to the battery module including the plurality of battery cells, and including a first switching element for generating AC;
one or more power consumption distribution parts connected in series to the AC generation switching part, and each including a second switching element for receiving the driving voltage through the plurality of driving voltage supply paths connected to the nodes of the plurality of battery cells;
a switching control part configured to control an on/off operation of the AC generation switching part according to a determined frequency for electrochemical impedance spectroscopy (EIS) measurement; and
a driving voltage output part configured to form the plurality of driving voltage supply paths through a plurality of driving voltage output elements connected to the nodes of the plurality of battery cells, wherein output terminals of the plurality of driving voltage output elements are connected to a single line in common and connected to the power consumption distribution part, and when any one of the plurality of driving voltage output elements is disconnected, the driving voltage output element connected to the node of the battery cell with the highest node voltage among the remaining driving voltage output elements outputs the driving voltage.

3. The electrochemical impedance spectroscopy measurement apparatus of claim 2, wherein the first switching element is a field effect transistor.

4. The electrochemical impedance spectroscopy measurement apparatus of claim 2, wherein the power consumption distribution part comprises:
a second switching element connected in series to the battery module including the plurality of battery cells;
a resistance element positioned between a gate terminal of the second switching element and output terminals of the plurality of driving voltage output elements, and connected thereto; and
a semiconductor device of which an input terminal is connected to a source terminal of the second switching element and of which an output terminal is connected to the gate terminal of the second switching element, and configured to induce a constant voltage output.

5. The electrochemical impedance spectroscopy measurement apparatus of claim 4, wherein the second switching element is a field effect transistor, and
the semiconductor device is a zener diode.

6. The electrochemical impedance spectroscopy measurement apparatus of claim 4, wherein the power consumption distribution part is configured to maintain the second switching element continuously in a turned-on state by causing a voltage at the gate terminal of the second switching element to be output higher than a voltage at the source terminal of the second switching element and to be output equal to or higher than a breakdown voltage of the semiconductor device.

7. The electrochemical impedance spectroscopy measurement apparatus of claim 2, wherein the plurality of driving voltage output elements are a plurality of diodes of which input terminals are respectively connected to the nodes of the plurality of battery cells and of which the output terminals are connected to the single line in common, and connected to the power consumption distribution part, and configured to output the highest node voltage among node voltages connected to the nodes of the plurality of battery cells to the power consumption distribution part.

8. The electrochemical impedance spectroscopy measurement apparatus of claim 2, wherein the AC discharge switching part further comprises:
a sensing resistor part positioned between, connecting the AC generation switching part and the battery module including the plurality of battery cells, and
the switching control part is configured to control an on/off cycle of the AC generation switching part by measuring a voltage applied to the sensing resistor part so as to maintain a determined AC frequency for electrochemical impedance spectroscopy (EIS) measurement.

9. The electrochemical impedance spectroscopy measurement apparatus of claim 8, wherein the sensing resistor part comprises one or more resistance elements.

10. An electrochemical impedance spectroscopy measurement method, comprising:
generating, by an AC discharge switching part electrically connected to a battery module including a plurality of battery cells, AC corresponding to a frequency for electrochemical impedance spectroscopy (EIS) measurement for the battery module;
performing, by an EIS measurement part connected to nodes of the plurality of battery cells included in the battery module, electrochemical impedance spectroscopy (EIS) measurement on each of the plurality of battery cells included in the battery module; and
responding to, by the AC discharge switching part when any one of a plurality of driving voltage supply paths connected to the nodes of the plurality of battery cells electrically connected to supply a driving voltage to a power consumption distribution switching element included in an AC discharge path is disconnected during electrochemical impedance spectroscopy (EIS) measurement for each of the plurality of battery cells, disconnection of the driving voltage by outputting the highest node voltage among the remaining driving voltage supply paths.

11. The electrochemical impedance spectroscopy measurement method of claim 10, wherein in the step of responding to the disconnection of the driving voltage, when a connection line for the highest node voltage is disconnected while the highest node voltage is output among node voltages connected to and output from the nodes of the plurality of battery cells, the AC discharge switching part outputs the next-highest node voltage among the remaining node voltages excluding the highest node voltage through the plurality of driving voltage supply paths.

12. The electrochemical impedance spectroscopy measurement method of claim 10, wherein in the step of responding to the disconnection of the driving voltage, while the highest node voltage is output among node voltages connected to and output from the nodes of the plurality of battery cells, when any one of connection lines to the remaining nodes other than the node having the highest output is disconnected, the AC discharge switching part maintains the output of the highest node voltage that is currently output through the plurality of driving voltage supply paths.

13. The electrochemical impedance spectroscopy measurement method of claim 10, wherein in the step of performing electrochemical impedance spectroscopy (EIS) measurement, during electrochemical impedance spectroscopy (EIS) measurement for each of the plurality of battery cells, a switching control part of the AC discharge switching part controls an on/off cycle of an AC generation switching part by measuring a voltage applied to a sensing resistor part so as to maintain a determined AC frequency for electrochemical impedance spectroscopy (EIS) measurement.

14. A battery system, comprising:
a battery module including a plurality of battery cells;
an EIS measurement device connected to each of a plurality of battery cells included in the battery module, and configured to perform electrochemical impedance spectroscopy (EIS) measurement on each of the plurality of battery cells during AC discharge of the battery module; and
an AC discharge switching device connected to the battery module to form an AC discharge path, and configured to supply a driving voltage to a power consumption distribution switching element included in the AC discharge path through a plurality of driving voltage supply paths connected to nodes of the plurality of battery cells.

15. The battery system of claim 14, wherein the AC discharge switching device comprises:
an AC generation switching part electrically connected to the battery module including the plurality of battery cells, and including a first switching element for generating AC;
one or more power consumption distribution parts connected in series to the AC generation switching part, and each including a second switching element for receiving the driving voltage through the plurality of driving voltage supply paths connected to the nodes of the plurality of battery cells;
a switching control part configured to control an on/off operation of the AC generation switching part according to a determined frequency for electrochemical impedance spectroscopy (EIS) measurement; and
a driving voltage output part configured to form the plurality of driving voltage supply paths through a plurality of driving voltage output elements connected to the nodes of the plurality of battery cells, wherein output terminals of the plurality of driving voltage output elements are connected to a single line in common and connected to the power consumption distribution part, and when any one of the plurality of driving voltage output elements is disconnected, the driving voltage output element connected to the node of the battery cell with the highest node voltage among the remaining driving voltage output elements outputs the driving voltage.

16. The battery system of claim 15, wherein the AC discharge switching device further comprises:
a sensing resistor part positioned between, connecting the AC generation switching part and the battery module including the plurality of battery cells,
the switching control part is configured to control an on/off cycle of the AC generation switching part by measuring a voltage applied to the sensing resistor part so as to maintain a determined AC frequency for electrochemical impedance spectroscopy (EIS) measurement.
